(19) United States
(12) Patent Application Publication
(10) Pub. No.: US 2014/0183606 A1
(43) Pub. Date: Jul. 3, 2014

(54) SEMICONDUCTOR DEVICE AND MANUFACTURING METHOD THEREOF

(71) Applicant: Kabushiki Kaisha Toshiba, Minato-ku (JP)

(72) Inventors: Kazunori KAKEHI, Oita (JP); Hisashi Aikawa, Oita (JP); Yosuke Kitamura, Oita (JP)

(73) Assignee: Kabushiki Kaisha Toshiba, Minato-ku (JP)

(21) Appl. No.: 13/904,448

(22) Filed: May 29, 2013

(30) Foreign Application Priority Data
Dec. 28, 2012 (JP) 2012-288027

(51) Int. Cl. H01L 27/146

(52) U.S. Cl. CPC H01L 27/14689; H01L 27/14643
USPC 257/290; 438/42

(57) ABSTRACT

According to an embodiment of the invention, there is provided a method of manufacturing a semiconductor device. The method of manufacturing the semiconductor device includes forming a trench downward from an upper face of a semiconductor layer at a position where an element isolation area is formed in the semiconductor layer, and melting the upper face of the trench-formed semiconductor layer to close an open end of the trench.

### CROSS-REFERENCE TO RELATED APPLICATION

This application is based upon and claims the benefit of priority from Japanese Patent Application No. 2012-288027, filed on Dec. 28, 2012; the entire contents of which are incorporated herein by reference.

### FIELD

An embodiment described herein relates generally to a semiconductor device and a manufacturing method thereof.

### BACKGROUND

In the related art, there is a technique of isolating elements among semiconductor elements by providing a hollow element isolation area among semiconductor devices provided to be adjacent. The hollow element isolation area is formed, for example, by forming a trench downward from an upper face of a semiconductor layer at a formation position of the element isolation area in the semiconductor layer and closing an open end of the trench.

However, when the hollow element isolation area is formed, there is a problem that a process of closing the open end of the trench is complex.

### BRIEF DESCRIPTION OF THE DRAWINGS

FIG. 1 is a diagram of a CMOS sensor in a top view according to an embodiment;

FIG. 2 is a diagram illustrating a part of a pixel unit in a cross-sectional view according to the embodiment;

FIGS. 3A to 3C are diagrams illustrating a manufacturing process of the CMOS sensor in a cross-sectional view according to the embodiment;

FIGS. 4A to 4C are diagrams illustrating a manufacturing process of the CMOS sensor in a cross-sectional view according to the embodiment; and

FIGS. 5A to 5C are diagrams illustrating a manufacturing process of the CMOS sensor in a cross-sectional view according to the embodiment.

### DETAILED DESCRIPTION

In general, according to an embodiment, a method of manufacturing a semiconductor device includes forming a trench downward from an upper face of a semiconductor layer at a position where an element isolation area is formed in the semiconductor layer, and melting the upper face of the trench-formed semiconductor layer to close an open end of the trench.

An exemplary embodiment of a semiconductor device and a manufacturing method thereof will be explained below in detail with reference to the accompanying drawings. The present invention is not limited to the following embodiment.

In the embodiment, as an example of the semiconductor device, a solid state image capturing device will be described by way of example. The solid state image capturing device according to the embodiment is a so-called back side illumination CMOS (Complementary Metal Oxide Semiconductor) image sensor in which a wiring layer is formed on the opposite face side to a face to which incident light of a light receiving element receiving the incident light and performing photoelectric conversion is input.

In addition, the solid state image capturing device according to the embodiment is not limited to the back side illumination CMOS image sensor, and may be an arbitrary image sensor such as a front side illumination CMOS image sensor and a CCD (Charge Coupled Device) image sensor.

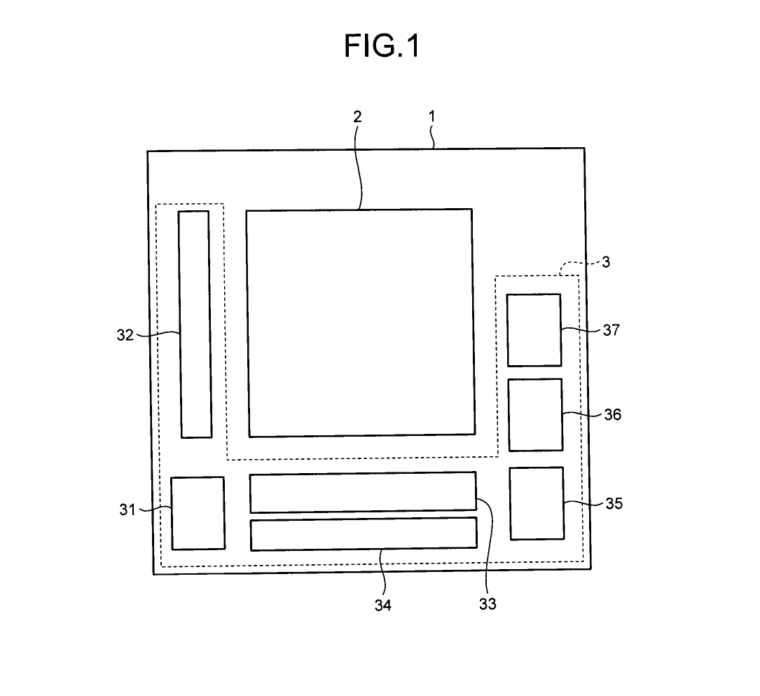

FIG. 1 is a diagram of the back side illumination CMOS image sensor (hereinafter, referred to as “CMOS sensor 1”) according to the embodiment in a top view. As illustrated in FIG. 1, the CMOS sensor 1 includes a pixel unit 2 and a logic unit 3.

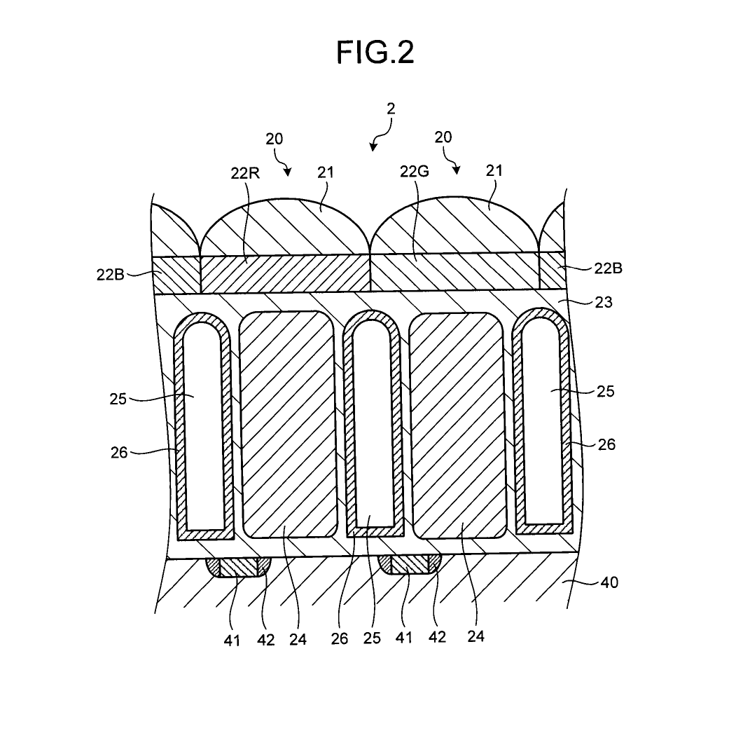

The pixel unit 2 includes a plurality of light receiving elements provided in a matrix. Each light receiving element photoelectrically converts incident light into negative charges based on a light reception amount (a light receiving intensity) and accumulates the charges in a charge accumulation area. In addition, a configuration of the light receiving element will be described below with reference to FIG. 2.

The logic unit 3 includes a timing generator 31, a vertical selection circuit 32, a sampling circuit 33, a horizontal selection circuit 34, a gain control circuit 35, an A/D (analog/digital) conversion circuit 36, and an amplification circuit 37.

The timing generator 31 is a processing unit that outputs a pulse signal as a reference of an operation timing for the pixel unit 2, the vertical selection circuit 32, the sampling circuit 33, the horizontal selection circuit 34, the gain control circuit 35, the A/D conversion circuit 36, and the amplification circuit 37.

The vertical selection circuit 32 is a processing unit that sequentially selects, for each row, the light receiving elements reading the charges from the plurality of light receiving elements disposed in a matrix. The vertical selection circuit 32 outputs the charges accumulated in each light receiving element selected for each row from the light receiving element to the sampling circuit 33 as a pixel signal representing brightness of each pixel.

The sampling circuit 33 is a processing unit that removes noise by CDS (Correlated Double Sampling), from the pixel signal input from each light receiving element selected for each row by the vertical selection circuit 32, and temporarily keeps the pixel signal.

The horizontal selection circuit 34 is a processing unit that sequentially selects and reads, for each column, the pixel signal kept in the sampling circuit 33, and outputs the pixel signal to the gain control circuit 35. The gain control circuit 35 is a processing unit that adjusts a gain of the pixel signal input from the horizontal selection circuit 34, and outputs the pixel signal to the A/D conversion circuit 36.

The A/D conversion circuit 36 is a processing unit that converts the analog pixel signal input from the gain control circuit 35 into a digital pixel signal, and outputs the digital pixel signal to the amplification circuit 37. The amplification circuit 37 is a processing unit that amplifies the digital signal input from the A/D conversion circuit 36, and outputs the amplified digital signal to a predetermined DSP (Digital Signal Processor (not illustrated)).

As described above, in the CMOS sensor 1, the plurality of light receiving elements disposed in the pixel unit 2 photoelectrically converts the incident light into the negative charges based on the light reception amount and accumulates the charges, and the logic unit 3 reads the charges accumulated in each photoelectric conversion element as the pixel signal, thereby performing the image capturing.

The CMOS sensor 1 is provided with a hollow element isolation area where the light receiving elements are electrically and optically isolated, among the light receiving elements provided to be adjacent in the pixel unit 2. In the CMOS sensor 1, by the element isolation area, leakage of the charges and the incident light from the photoelectric conversion element to the adjacent photoelectric conversion elements is prevented. Next, a configuration of the pixel unit 2 provided with the hollow element isolation area will be described with reference to FIG. 2.

FIG. 2 is a diagram illustrating a part of the pixel unit 2 according to the embodiment in a cross-sectional view. In addition, FIG. 2 schematically illustrates a cross section of two light receiving elements corresponding to two pixels in the pixel unit 2.

As illustrated in FIG. 2, the pixel unit 2 is provided with light receiving elements 20 that are a plurality of semiconductor elements. Each light receiving element 20 is provided with an N-type Si area 24 provided in a P-type Si (silicon) layer 23. In the light receiving element 20, a photodiode formed by PN junction between the P-type Si layer 23 and the N-type Si area 24 serves as the photoelectric conversion element, and each photoelectric conversion element photoelectrically converts the incident light into negative charges based on the light reception intensity. The photoelectrically converted charges are accumulated in the N-type Si area 24 in each photoelectric conversion element.

In addition, each light receiving element 20 is provided with any one of color filters 22R, 22G, and 22B on the face side to which the incident light is input in the P-type Si layer 23. Herein, the color filter 22R is a filter of allowing the red incident light to selectively pass, the color filter 22G is a filter allowing the green incident light to selectively pass, and the color filter 22B is a filter of allowing the blue incident light to selectively pass.

In addition, herein, although not illustrated, a protective film, a planarization film, an antireflection film, and a fixation charge layer that keeps negative fixation charges are provided between the P-type Si layer 23 and the color filters 22R, 22G, and 22B.

In addition, each light receiving element 20 is provided with a micro-lens 21 on the incident side face of the incident light of the color filters 22R, 22G and 22B. The micro-lens 21 is a flat convex lens that collects the incident light to the corresponding N-type Si area 24.

In addition, each light receiving element 20 is provided with a reading gate 41 that reads the charges from each N-type Si area 24, at a predetermined position on the opposite face to the incident side of the incident light of the P-type Si layer 23. A side wall 42 is provided on a peripheral face of each reading gate 41. The reading gate 41 and the side wall 42 are provided in an interlayer insulating film 40.

In addition, herein, although not illustrated, the interlayer insulating film 40 is provided with a multilayer wiring other than the reading gate 41. The multilayer wiring is used to read the photoelectrically converted charges and to transmit a driving signal to the other circuit element (not illustrated) provided in the CMOS sensor 1.

The pixel unit 2 is provided with a hollow element isolation area 25 that is provided between the light receiving elements 20 provided to be adjacent so as to electrically and optically isolate the light receiving elements 20. Herein, each element isolation area 25 is provided in the P-type Si layer 23 positioned between the N-type Si areas 24 that are the charge accumulation areas of the light receiving elements 20, and is a cavity in which the face (herein, the upper face) of the incident side of the incident light of the P-type Si layer 23 is melted and an upper portion is closed.

According to the hollow element isolation area 25, the air in the cavity is a barrier preventing the charges from passing, and thus it is possible to prevent the charged accumulated in the N-type Si areas 24 provided to be adjacent from leaking from the N-type Si areas 24.

That is, the hollow element isolation area 25 electrically isolates the light receiving elements 20 provided to be adjacent. Accordingly, in the CMOS sensor 1, it is possible to suppress occurrence of a crosstalk based on an electrical factor caused by the leakage of the charges from the light receiving element 20 to the light receiving elements 20 provided to be adjacent.

In addition, in the hollow element isolation area 25, an optical refractive index of air therein is 1, and is lower than an optical refractive index of Si. Accordingly, for example, even when the incident light input to the light receiving element 20 in an oblique direction obliquely passes through the N-type Si area 24 and the P-type Si layer 23, the incident light is reflected by the air with the optical refractive index lower than that of Si in the inner peripheral face of the cavity.

That is, the hollow element isolation area 25 optically isolates the light receiving elements 20 provided to be adjacent. Accordingly, in the CMOS sensor 1, it is possible to suppress the occurrence of the crosstalk based on the optical factor caused by incursion of the incident light from the light receiving elements 20 to the light receiving elements 20 provided to be adjacent.

In addition, the upper portion of the hollow element isolation area 25 according to the embodiment is closed by the melted Si on the upper face of the P-type Si layer 23. That is, the hollow element isolation area 25 is formed such that the upper portion thereof is closed by a simple and easy process of melting the upper face of the P-type Si layer 23, without performing a complex process such as forming a separate semiconductor layer to close the upper portion.

In addition, the hollow element isolation area 25 is provided with a termination film 26 subjected to a process of terminating a dangling bond in the inner peripheral face. Accordingly, in the element isolation area 25, the dangling bond is terminated in the inner peripheral face, and thus it is possible to reduce dark current by suppressing the occurrence of the charges caused by an interface state occurring by the dangling bond.

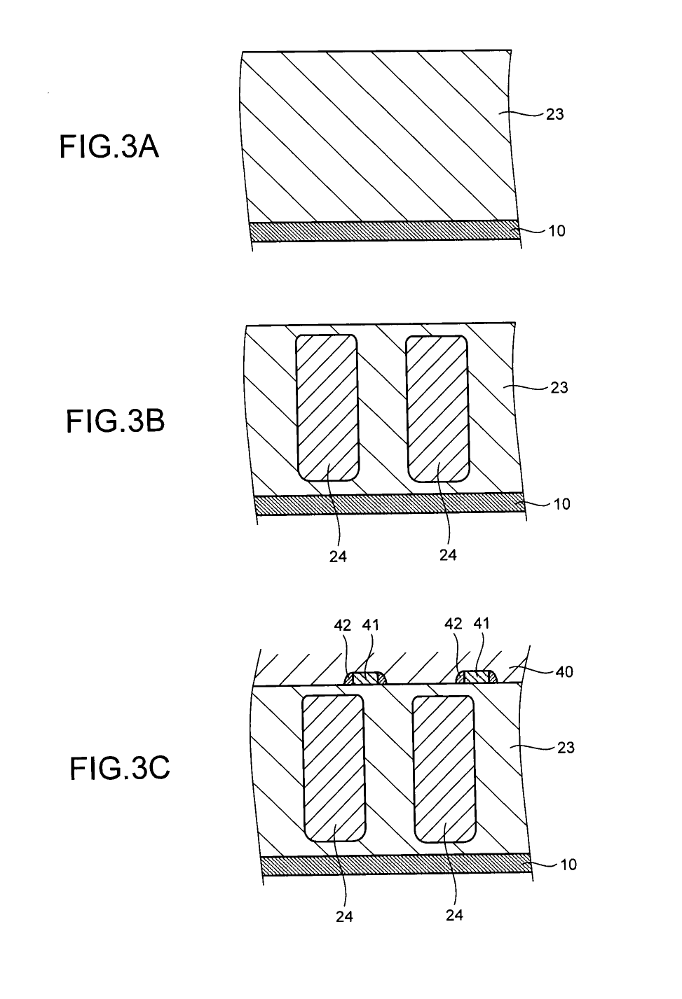

Next, a method of manufacturing the CMOS sensor 1 according to the embodiment will be described with reference to FIGS. 3A to 5C. In addition, a method of manufacturing the logic unit 3 in the CMOS sensor 1 is the same as that of the general CMOS sensor in the related art. For this reason, hereinafter, a method of manufacturing the pixel unit 2 in the CMOS sensor 1 will be described, and the method of manufacturing the logic unit 3 will not be described.

FIGS. 3A to 5C are diagrams illustrating a process of manufacturing the CMOS sensor 1 according to the embodiment in a cross-sectional view. In addition, in FIGS. 3A to 5C, a process of manufacturing two pixel portions in the pixel unit 2 is schematically illustrated.

As illustrated in FIG. 3A, when the CMOS sensor 1 is manufactured, a P-type Si layer 23 is formed on a semiconductor substrate 10 such as an Si wafer. In this case, for example, an Si layer into which P-type impurities such as B (boron) are doped is epitaxially grown on the semiconductor substrate 10 to form a P-type Si layer 23. In addition, the P-type Si layer 23 may be formed by performing ion implantation of P-type impurities into the Si wafer and performing an annealing process.

Subsequently, as illustrated in FIG. 3B, ion implantation of N-type impurities such as P (phosphorus) is performed from the upper face in a predetermined area of the P-type Si layer 23, and then an annealing process is performed to form N-type Si areas 24. In addition, the plurality of N-type Si areas 24 is disposed in a matrix in the top view.

In such a manner, the N-type Si area 24 is embedded in the P-type Si layer 23, PN junction is formed, and a photoelectric conversion element that is a photodiode is formed. In addition, the N-type Si area 24 is a charge accumulation area where photoelectrically converted negative charges are accumulated, and the junction face side to the semiconductor substrate 10 is exposed later and becomes a light receiving face of incident light.

Subsequently, as illustrated in FIG. 3C, a reading gate 41 and a side wall 42 are formed at a predetermined position on the upper face of the P-type Si layer 23 through a gate oxide film (not illustrated), and then an interlayer insulating film 40 is formed.

Subsequently, a multilayer wiring (not illustrated) are formed in the interlayer insulating film 40. The multilayer wiring is formed, for example, by repeating a process of forming the interlayer insulating film 40 such as an Si oxide film, a process of forming a predetermined wiring pattern in the interlayer insulating film 40, and a process of forming a wiring of embedding Cu or the like in the wiring pattern.

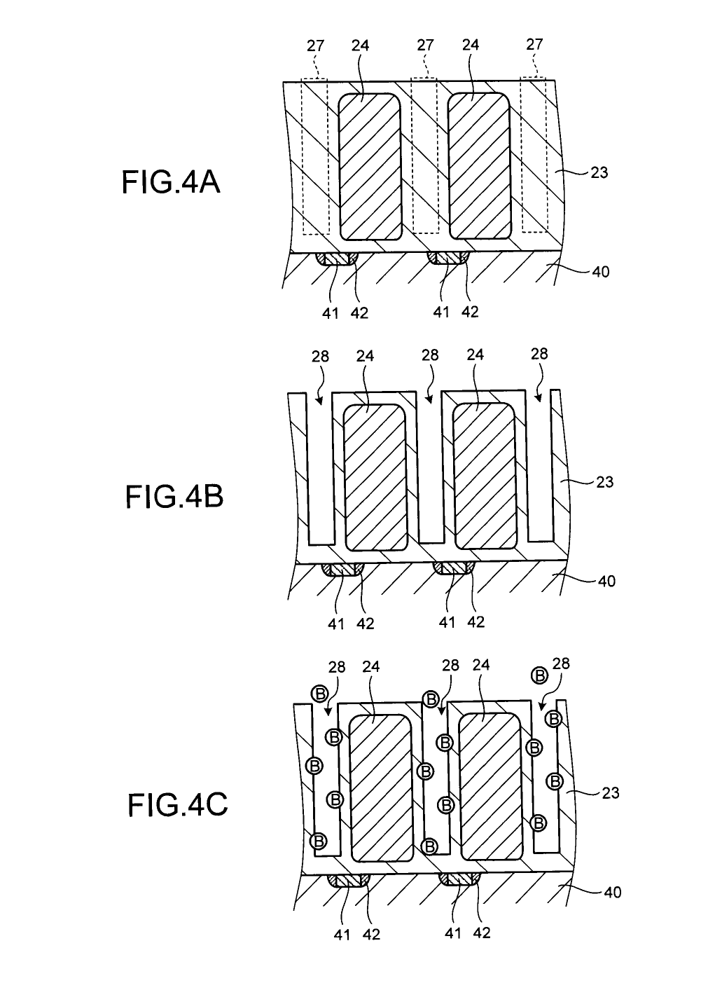

Thereafter, on the upper face of the interlayer insulating film 40, for example, a support substrate (not illustrated) such as an Si wafer is bonded, and the support substrate and the semiconductor substrate 10 are reversed upside down. By grinding the back face side of the semiconductor substrate 10 positioned upside, as illustrated in FIG. 4A, the back face (herein, the upper face) of the P-type Si layer 23 is exposed.

Subsequently, a hollow element isolation area 25 (see FIG. 2) is formed at a position indicated by a dot line 27 of FIG. 4A. Specifically, first, as illustrated in FIG. 4B, a trench 28 is formed downward from the upper face of the P-type Si layer 23 to surround the periphery of the N-type Si area 24.

In this case, for example, on the upper face of the P-type Si layer 23, a resist in which a formation position of the trench 28 is selectively opened is provided, and anisotropic dry etching with the resist as a mask is performed to form the trench 28.

In the inner peripheral face of the trench 28 formed as described above, a dangling bond is generated, and an interface state occurs. When the interface state occurs in the inner peripheral face of the trench 28 as described above, negative charges are generated in the P-type Si layer 23 irrespective of the incident light by the interface state, and are accumulated in the N-type Si area 24.

The negative charges generated irrespective of the incident light become dark current, which is detected, to cause a hot pixel and a crosstalk in the captured image by detection of dark current. Therein, in the embodiment, after forming the trench 28, a process of terminating the dangling bond is performed on the inner peripheral face of the trench 28.

Specifically, as illustrated in FIG. 4C, the same predetermined conductive impurities as the inner peripheral face of the trench 28 are injected into the trench 28. Herein, since the inner peripheral face of the trench 28 is P-type Si, for example, P-type B (boron) is injected into the trench 28.

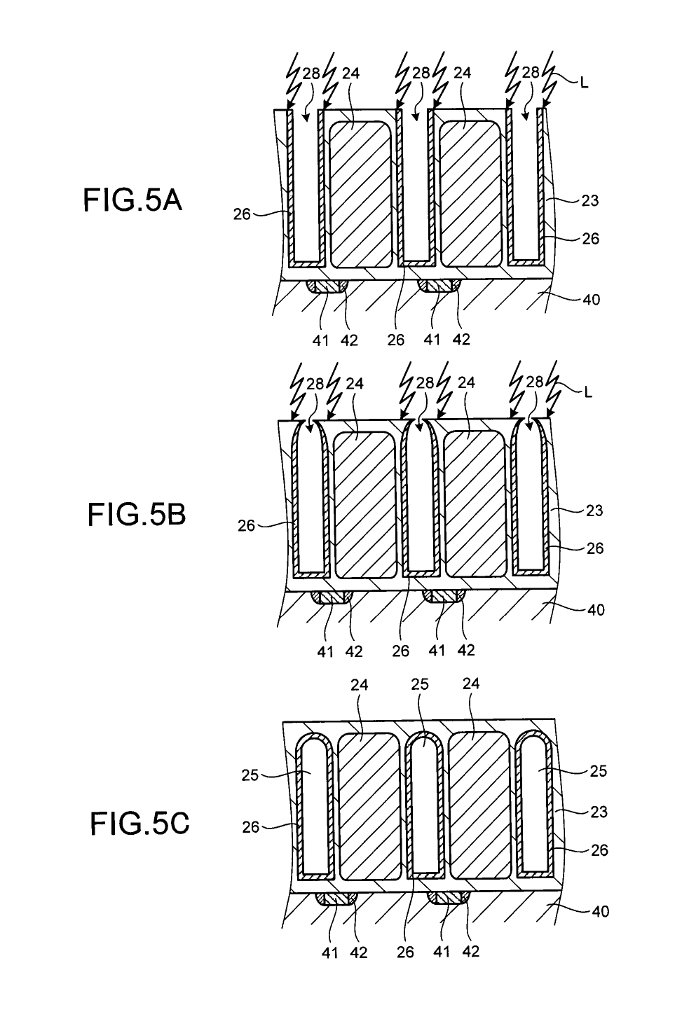

The B injected into the trench 28 is diffused as a solid layer from the inner peripheral face of the trench 28 into the P-type Si layer 23, as illustrated in FIG. 5A, and a termination film 26 of terminating the dangling bond is formed in the inner peripheral face of the trench 28.

Accordingly, the dangling bond in the inner peripheral face of the trench 28 is terminated, and thus it is possible to suppress occurrence of the negative charges irrespective of the incident light in the inner peripheral face of the trench 28.

In addition, in the embodiment, the termination film 26 is formed by diffusing the B as a solid layer from the inner peripheral face of the trench 28 into the P-type Si layer 23, and thus it is possible to form the termination film 26 with a uniform thickness throughout the inner peripheral face of the trench 28.

Thereafter, in the embodiment, the upper face of the P-type Si layer 23 in which the trench 28 is formed is melted, and the upper open end of the trench 28 is closed, to form the hollow element isolation area 25 (see FIG. 2).

Specifically, as illustrated in FIG. 5A, first, the upper face of the P-type Si layer 23 around the upper open end in the trench 28 is selectively irradiated with laser L to perform laser annealing. In the laser annealing, the upper face of the P-type Si layer 23 is heated to about 1000° C., for example, for several seconds.

Accordingly, as illustrated in FIG. 5B, Si of a portion irradiated with the laser L in the upper face of the P-type Si layer 23 is selectively heated and melted. The upper open end of the trench 28 is closed by the melted Si, and as illustrated in FIG. 5C, the hollow element isolation area 25 is formed.

As described above, in the embodiment, the upper face of the P-type Si layer 23 is selectively heated and melted by the laser annealing, and thus it is possible to prevent a portion other than the upper face of the P-type Si layer from being unnecessarily heated. Accordingly, when the surface of the P-type Si layer 23 is melted, for example, it is possible to prevent a problem that the multilayer wiring provided in the interlayer insulating film 40 is melted out from occurring.

In addition, in this case, the termination film 26 of the inner peripheral face in the upper open end of the trench 28 is also melted to close the upper open end of the trench 28. Accordingly, the inner peripheral face of the hollow element isolation area 25 is coated by the termination film 26. Therefore, according to the hollow element isolation area 25, it is possible to suppress the occurrence of the interface state caused by the dangling bond in the inner peripheral face of the cavity.

As described above, in the embodiment, only by performing the simple and easy process of selectively melting the upper face of the P-type Si layer 23 in which the trench 28 is formed, it is possible to form the hollow element isolation area 25 by easily closing the upper open end of the trench 28 without performing a complex process.

Thereafter, color filters 22R, 22G, and 22B and a micro-lens 21 are sequentially formed on the upper face of the P-type Si layer 23 in which the hollow element isolation area 25 is formed, and the CMOS sensor 1 provided with the pixel unit 2 illustrated in FIG. 2 is manufactured.

As described above, the method of manufacturing the semiconductor device according to the embodiment includes forming the trench downward from the upper face of the semiconductor layer at the position where the element isolation area is formed in the semiconductor layer, and melting the upper face of the trench-formed semiconductor layer to close the open end of the trench.

According to the method of manufacturing the semiconductor device, only by melting the upper face of the semiconductor layer in which the trench is formed at the formation position of the element isolation area, it is possible to form the hollow element isolation area by closing the open end of the trench without performing the complex process.

In addition, in the method of manufacturing the semiconductor device according to the embodiment, the open end of the trench is closed by selectively melting the upper face of the semiconductor layer by the laser annealing. Accordingly, it is possible to suppress the unnecessary heating of the portion other than the open end of the trench.

Accordingly, for example, like a case of manufacturing the back side illumination CMOS sensor described above, even when the upper face of the semiconductor layer is melted after a constituent element with relatively low heat resistance such as the multilayer wiring is formed, it is possible to reduce an influence of the heat melting the semiconductor layer which is adversely affected on the multilayer wiring.

In addition, the method of manufacturing the semiconductor device according to the embodiment further includes terminating the dangling bond in the inner peripheral face of the trench. Accordingly, it is possible to suppress the occurrence of the charges caused by the interface state in the inner peripheral face of the trench, and thus it is possible to reduce dark current.

In the method of manufacturing the semiconductor device according to the embodiment, by diffusing the same predetermined conductive impurities as the inner peripheral face of the trench from the inner peripheral face of the trench to the semiconductor layer, the termination film terminating the dangling bond is formed on the inner peripheral face of the trench.

As described above, by forming the termination film by the diffusion of the impurities, it is possible to form the termination film with a uniform film thickness throughout the inner peripheral face of the trench. In addition, in the process of forming the termination film on the inner peripheral face of the trench, when the impurities are diffused even on the upper face of the semiconductor layer, it is possible to also terminate the dangling bond on the upper face of the semiconductor layer at the same time, and it is possible to reduce the further dark current.

In addition, the process of forming the termination film on the inner peripheral face of the trench is not limited to the diffusion of the impurities. For example, a wet oxidization process or a dry oxidization process may be performed on the inner peripheral face of the trench, to form an oxide film as the termination film on the inner peripheral face of the trench. Even by forming the oxide film as the termination film, it is possible to terminate the dangling bond in the inner peripheral face of the trench.

In addition, the hollow element isolation area according to the embodiment is not limited to the space between the light receiving elements of the solid state image capturing device, and may be provided at a position of isolating arbitrary semiconductor elements such as transistors or capacitors formed on the semiconductor layer. That is, the hollow element isolation area according to the embodiment may be provided as STI (Shallow Trench Isolation) or DTI (Deep Trench Isolation) in an arbitrary semiconductor device.

While a certain embodiment has been described, the embodiment has been presented by way of example only, and is not intended to limit the scope of the inventions. Indeed, the novel embodiment described herein may be embodied in a variety of other forms; furthermore, various omissions, substitutions and changes in the form of the embodiment described herein may be made without departing from the spirit of the inventions. The accompanying claims and their equivalents are intended to cover such forms or modifications as would fall within the scope and spirit of the inventions.

What is claimed is:

1. A method of manufacturing a semiconductor device comprising:
forming a trench downward from an upper face of a semiconductor layer at a position where an element isolation area is formed in the semiconductor layer; and
melting the upper face of the trench-formed semiconductor layer to close an open end of the trench.

2. The method of manufacturing the semiconductor device according to claim 1, further comprising selectively melting the upper face of the semiconductor layer by laser annealing to close the open end of the trench.

3. The method of manufacturing the semiconductor device according to claim 1, further comprising selectively melting the open end of the trench on the upper face of the semiconductor layer by laser annealing to close the open end of the trench.

4. The method of manufacturing the semiconductor device according to claim 1, further comprising terminating a dangling bond in an inner peripheral face of the trench.

5. The method of manufacturing the semiconductor device according to claim 4, further comprising diffusing a predetermined conductive type of impurities from the inner peripheral face of the trench to the semiconductor layer to terminate the dangling bond.

6. The method of manufacturing the semiconductor device according to claim 5, further comprising diffusing the predetermined conductive type of impurities by solid phase diffusion.

7. The method of manufacturing the semiconductor device according to claim 4, further comprising oxidizing the inner peripheral face of the trench to terminate the dangling bond.

8. The method of manufacturing the semiconductor device according to claim 4, further comprising terminating the dangling bond in the upper face of the semiconductor layer at the same time as terminating the dangling bond in the inner peripheral face of the trench.

9. The method of manufacturing the semiconductor device according to claim 1, wherein an optical refractive index of gas in the trench is lower than an optical refractive index of the semiconductor layer.

10. The method of manufacturing the semiconductor device according to claim 9, wherein the gas is air.

11. The method of manufacturing the semiconductor device according to claim 1, wherein the trench is formed at a position where a plurality of light receiving elements provided in a solid state image capturing device is isolated.

12. A semiconductor device comprising:
a plurality of semiconductor elements that are formed on a semiconductor layer; and
a hollow element isolation area that is provided among the semiconductor elements provided to be adjacent, an upper portion of which is closed by melting an upper face of the semiconductor layer.

13. The semiconductor device according to claim 12, further comprising, in an inner peripheral face of the hollow element isolation area, a termination film that terminates a dangling bond of the inner peripheral face.

14. The semiconductor device according to claim 13, wherein the termination film is a thin film that is formed by diffusing a predetermined conductive type of impurities into the trench.

15. The semiconductor device according to claim 13, wherein the termination film is a thin film that is formed by oxidizing the inner peripheral face of the trench.

16. The semiconductor device according to claim 12, wherein the hollow element isolation area is provided with gas with an optical refractive index therein lower than an optical refractive index of the semiconductor layer.

17. The semiconductor device according to claim 16, wherein the gas is air.

18. The semiconductor device according to claim 12, wherein the semiconductor element is a light receiving element that is provided in a solid state image capturing device.
